(19) United States
(12) Patent Application Publication
(10) Pub. No.: US 2026/0094535 A1
(43) Pub. Date: Apr. 2, 2026

(54) ELECTRIC GROUNDING SIMULATOR

(71) Applicant: M.J. Electric, LLC, Iron Mountain, MI (US)

(72) Inventor: Steven Paul Kopp, Cambridge, NY (US)

(21) Appl. No.: 19/347,349

(22) Filed: Oct. 1, 2025

Related U.S. Application Data
(60) Provisional application No. 63/702,277, filed on Oct. 2, 2024.

(51) Int. Cl. G09B 9/00; G01R 27/20; G01R 31/58; G09B 19/24

(52) U.S. Cl. CPC G09B 9/00; G01R 27/205; G01R 31/58; G09B 19/24

(57) ABSTRACT

Grounding simulation models for training linemen and other power or utility technicians are disclosed. The grounding simulation models can be configured to provide equipotential zone (EPZ) grounding training for high voltage electric power transmission. In some instances, the grounding simulation models can include a power pole assembly including power poles, a top conductor, a middle conductor, a bottom conductor and an optical ground wire (OPGW). In some instances, the grounding simulation models can include a lineman meter configured to emulate a utility worker operating on high voltage electric power lines. In some instances, the grounding simulation model can include step leads that can be positioned anywhere along a matrix pattern on a mounting board, wherein the step leads are configured to demonstrate step and touch potential. In some instances, the grounding simulation models can include a model wire puller and insulation and isolation platforms.

### PRIORITY APPLICATIONS

This application claims priority to U.S. Provisional Patent Application No. 63/702,277, filed Oct. 2, 2024, which is incorporated herein by reference. Any and all applications for which a foreign or domestic priority claim is identified in the Application Data Sheet as filed with the present application are hereby incorporated by reference under 37 CFR 1.57.

### BACKGROUND

### Field

This application relates to a grounding simulation model for providing instruction and training related to equipotential zone (EPZ) grounding. In particular, this application relates to a grounding simulation model configured to provide instruction and training related to EPZ grounding for operation on high voltage power lines.

### Description

Electric workers, such as linemen, often use grounding systems while working on power lines or other electrical components in order to protect themselves against electric shock, which in some cases can be fatal. In general, the grounding systems are designed to place the electric worker in an equipotential zone that protects the worker from electric shock. An equipotential zone is a work zone in which the worker is protected from the possibility of current flowing across the worker's body from differences in electrical potential between objects in the work area. These differences in potential can be caused by, for example, induced voltage, line reenergization, or lightning. The worker in an equipotential zone is protected from electrical shock because there is a near identical state of electrical potential between any two points on the body. Establishing grounding to create an equipotential zone is thus extremely important.

### SUMMARY

Grounding simulation models for training linemen and other power or utility technicians are disclosed. The grounding simulation models can be configured to provide equipotential zone (EPZ) grounding training for high voltage electric power transmission. In some instances, the grounding simulation models can include a power pole assembly including power poles, a top conductor, a middle conductor, a bottom conductor and an optical ground wire (OPGW). In some instances, the grounding simulation models can include a lineman meter configured to emulate a utility worker operating on high voltage electric power lines. In some instances, the grounding simulation models can include step leads configured to demonstrate step and touch potential. In some instances, the grounding simulation models can include a model wire puller and insulation and isolation platforms.

In one aspect, a simulation model for providing EPZ grounding training is described. The simulation model includes: a power line model including a control system, at least one power pole assembly configured to support at least one conductor, at least one conductor coupled to the at least one power pole assembly, where the conductor is configured to receive and carry a current supplied from the control system, a mounting board configured to mount the at least one power pole assembly. The mounting board including at least one ground potential point wherein the at least one ground potential point is magnetic and electrically coupled by a wire that runs between the at least one ground potential points. The simulation model also includes a lineman meter configured for use during EPZ grounding training, where the lineman meter includes at least two appendage leads, a lineman meter housing, and a control screen configured to display a measured potential difference between the at least two appendage leads.

In some embodiments the simulation model further comprises a resistor positioned on the wire between adjacent ground potential points.

In some embodiments, the power line model of the simulation model further comprises at least one optical ground wire (OPGW).

In some embodiments the power pole assembly of the simulation model comprises at least one structure grounding point.

In some embodiments the mounting board of the simulation model comprises at least one grounding rod configured to provide a path to ground for the at least one power pole assembly.

In some embodiments, the power line model of the simulation model further comprises at least one jumper wire configured to arrange grounding setups for providing equipotential zone grounding training.

In some embodiments, the lineman meter of the simulation model is configured to be attached to the at least one conductor of the power line model using the at least two appendage leads to provide equipotential zone grounding training.

In some embodiments, the simulation model further includes a grounding simulator application, wherein the lineman meter is configured to interact with the grounding simulator application to display the measured potential difference on an external screen.

In some embodiments, the lineman meter is further configured to interact with the grounding simulator application to further display a measured potential at each of the at least two appendage leads.

In another aspect, a simulation model for providing EPZ grounding training. The model includes a power line model including a control system, at least one power pole assembly configured to support at least one conductor, at least one conductor coupled to the at least one power pole assembly, wherein the at least one conductor is configured to receive and carry a current supplied form the control system. The power line model further include a mounting board configured to mount the at least one power pole assembly. The mounting board including at least one ground potential point wherein the at least one ground potential point is magnetic. The simulation model further including a lineman meter configured for use during EPZ grounding training, where the lineman meter includes at least two appendage leads, a lineman meter housing, and a control screen configured to display a measured potential difference between the at least two appendage leads.

In some embodiments, the simulation model further includes a step and touch potential model including at least one step lead magnetically coupled to one of the at least one ground potential points.

In some embodiments, the step and touch potential model is positioned on the mounting board.

In some embodiments, the a wire is positioned in the mounting board running between the at least one ground potential points to electrically couple the at least one ground potential points.

In some embodiments, the simulation model further includes a resistor positioned on the wire between adjacent ground potential points.

In some embodiments, the lineman meter is configured to be attached to the at least one step lead using the at least two appendage leads to provide EPZ grounding training.

In some embodiments, the simulation model further includes a grounding simulator application, wherein the lineman meter is configured to interact with the grounding simulator application to display the measured potential difference on an external screen.

In another aspect, the simulation model for providing EPZ grounding training can include: a power line model including: a control system, at least one power pole assembly configured to support at least on conductor, at least one conductor attached to the at least one power pole assembly, configured to receive and carry a current supplied from the control system. The power line model further including a mounting board configured to mount the at least one power pole assembly, where the mounting board includes at least one ground potential point where the at least one ground potential point is magnetic. The powerline model further including a lineman meter for use during EPZ grounding training, the lineman meter including at least two appendage leads; a lineman meter housing; and a control screen configured to display a measured potential difference between the at least two potential leads.

In some embodiments, the at least one ground potential points are arranged in a grid pattern.

In some embodiments, the at least one ground potential points are electrically coupled by a wire that runs between them.

In some embodiments, a resistor is positioned on the wire between adjacent ground potential points.

### BRIEF DESCRIPTION OF THE DRAWINGS

The features and advantages of the devices, systems, and methods of the grounding simulation models described herein will become more fully apparent from the following description and appended claims, taken in conjunction with the accompanying drawings. These drawings depict only several embodiments in accordance with the disclosure and are not to be considered limiting of its scope. In the drawings, similar reference numbers or symbols typically identify similar components, unless context dictates otherwise. The drawings may not be to scale.

FIG. 1 is a front view of an embodiment of a grounding simulation model configured for providing EPZ grounding training comprising three power pole assemblies.

FIG. 2 is a front view of an embodiment of a power pole assembly of a grounding simulation model configured for providing EPZ grounding training.

FIG. 3A is a perspective left side view of an embodiment of a power pole assembly coupled with an optical ground wire (OPGW).

FIG. 3B is a perspective left side view of an embodiment of a power pole assembly disconnected from an OPGW.

FIG. 4 is a perspective left side view of an embodiment of a power pole assembly.

FIG. 5 is a front view of a base of a power pole assembly and a ground rod.

FIG. 6 depicts the underside of the base of a power pole assembly.

FIG. 7 depicts a base plate for the base of the power pole assembly.

FIG. 8 depicts an embodiment of a lineman meter configured to emulate a utility worker on a grounding simulation model and display voltage difference experienced by the utility work in a given configuration.

FIG. 9 depicts an embodiment of a meter screen of the lineman meter of FIG. 8 configured to show if there are hazardous conditions.

FIG. 10 depicts an embodiment of an external screen with a grounding simulator application downloaded and displayed, configured to show if the lineman meter of FIG. 8 is configured in a hazardous condition.

FIG. 11 depicts the lineman meter of FIG. 8 coupled to the grounding simulation model of FIG. 1, wherein the model is configured such that an EPZ is established, and the lineman meter is configured in a safe condition.

FIG. 12 depicts the lineman meter of FIG. 8 coupled to the grounding simulation model of FIG. 1, wherein the model is configured such that an EPZ is not established, and the lineman meter is configured in a hazardous condition.

FIG. 13A depicts a top view of the first mounting board surface.

FIG. 13B depicts an internal view of the first mounting board.

FIG. 13C depicts a view of a power pole assembly connection point on a mounting board.

FIG. 14A depicts a top view of the second mounting board surface.

FIG. 14B depicts an internal view of the second mounting board.

FIG. 15 depicts a lineman meter coupled to a step and touch potential model.

FIG. 16A depicts a front perspective of a second mounting board comprising a model wire puller, grounding mats, and insulation or isolation mat.

FIG. 16B depicts a top-down view of the second mounting board, comprising a wire puller, grounding mats, and insulation or isolation mat.

FIG. 17 depicts an embodiment of two wire puller models.

FIG. 18A depicts a top-down view of a grounding mat.

FIG. 18B depicts a bottom-up view of a grounding mat.

FIG. 19A depicts a schematic of top of a connection strap.

FIG. 19B depicts an internal schematic of a connection strap.

FIG. 20 depicts two grounding mats connected via a connection strap.

FIG. 21 depicts an arrangement of grounding mats electrically connected via connection straps.

FIG. 22 depicts a wire puller grounding board.

FIG. 23A is a top perspective view of an insulation or isolation mat.

FIG. 23B depicts an insulation or isolation mat on its side.

FIG. 24 depicts a mounting board held within a carrying case.

FIG. 25 depicts the ground simulation model packed into a carrying case.

### DETAILED DESCRIPTION OF THE PREFERRED EMBODIMENT

Disclosed herein are embodiments of grounding simulation models for linemen or other power or utility technicians. In some embodiments, the grounding simulation models are of a suitable size for use and display on a tabletop; however, this need not be the case in all embodiments. The grounding simulation models can be configured to provide training and/or testing related to a wide variety of concepts and skills that are needed for working with dangerous power lines and related components. In particular, the grounding simulation models can be configured to provide training relating to EPZ grounding and step and touch potential in power line applications. In some embodiments, the grounding simulation models are configured to simulate high voltage conditions using safe and low voltages for testing and training purposes.

### Power Line Model

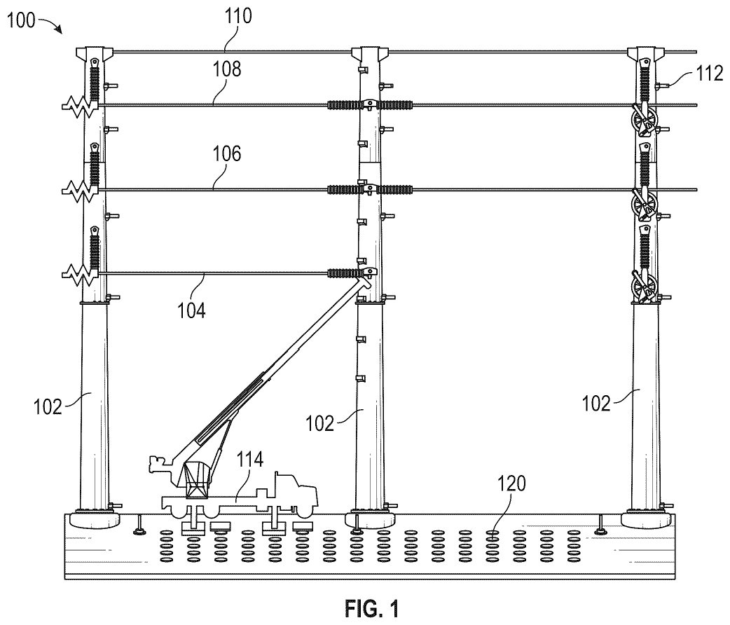

FIGS. 1-7 illustrate various views of embodiments of a power line model 100 of a grounding simulation model configured for providing EPZ grounding training. As will be described in more detail below, the power line model 100 can be configured for providing EPZ grounding training relating to operation on overhead, pole-mounted power lines and associated electrical equipment.

In the illustrated embodiment, the power line model 100 comprises three power pole assemblies 102, three conductor lines 104, 106, 108 and one optical ground wire (OPGW) 110. In alternative embodiments, the power line model 100 may comprise more than three power pole assemblies 102 (e.g., four, five, six or more power pole assemblies 102). In alternative embodiments the power line model 100 may comprise less than three power pole assemblies 102 (e.g., two, or one power pole assemblies 102). In alternative embodiments, the power line model 100 may comprise more than three conductor lines 104, 106, 108 (e.g., four, five, six or more conductor lines 104, 106, 108). In alternative embodiments, the power line model 100 may comprise less than three conductor lines 104, 106, and 108 (e.g., two or one conductor lines 104, 106, 108). In alternative embodiments, the power line model 100 may comprise more than one OPGW 110 (e.g., two, three, four, five or more OPGWs 110). In alternative embodiments, the power line model 100 may comprise zero OPGWs 110. In general, the power line model 100 is configured with conductors and an OPGW in a manner similar to that experienced in the field, only at a smaller scale and operating lower and safer voltages for training. For example, in some embodiments, the power line model 100 can be configured for table top and/or classroom use.

FIG. 1 illustrates an embodiment of the power line model 100 with several of its subcomponents, including power pole assemblies 102 and their various components. Generally, the power line model 100 and its components can be customized to mirror real life working conditions on overhead power lines to simulate voltage differences in order to demonstrate the dangerous conditions that a worker can encounter without proper setup while working on overhead power lines and the proper configure of EPZs on the overhead powerlines.

FIG. 1 is a front perspective view of an embodiment of the power line model 100 of the grounding simulation model. As seen in the figure, the power line model 100 comprises power pole assemblies 102, a bottom conduct 104, a middle conductor 106, and a top conductor 108, an OPGW 110, structure grounding points 112, an aerial work platform 114, and a first mounting board 120. In some embodiments the aerial work platform 114 can be a model of a bucket truck. In some embodiments the aerial work platform 114 can be a model of a cherry picker truck. Not shown in the figure, the power line model 100 can comprise a power line control system 122 that comprises wires, a portion of which are positioned inside the power pole assemblies 102. The power line control system 122 can be configured to provide power to the power line model 100 so the three conductors 104, 106, and 108 can be energized at low and safe voltages since the model is used for training purposes.

The embodiment of the power line model 100 shown in FIG. 1 has three power pole assemblies 102 (discussed further herein). The three conductors 104, 106, and 108 as well as the OPGW 110 can be configured to emulate the function of real conductors and OPGWs on an overhead power line. The three conductors 104, 106, 108 as well as the OPGW 110 are each continuous and coupled to the three power pole assemblies 102 such that they are parallel with each other. The three conductors 104, 106, 108 and the OPGW 110 extend mechanically and electrically continuously across the three power pole assemblies. In some embodiments, the three conductors 104, 106, and 108 and the OPGW 110 extend mechanically and electrically continuously across the three power pole assemblies 102 via jumpers (not depicted) coupled to the three conductors 104, 106, and 108 and the OPGW 110 about the middle power pole assembly 102.

In practice, OPGWs serve to provide telecommunication capabilities and to shield conductors from lightning and other dangerous weather conditions and provide a direct source to ground. For purposes of the present disclosure, the OPGW 110 of the power line model 100 can act as a direct source to ground. The structure grounding points 112 can be configured to simulate real structure grounding points that utility workers stand on while operating on a real overhead power line. Not depicted here, jumper wires or temporary grounding jumper wires can be coupled to the structure grounding points 112 for creating simulated situations a worker might encounter.

The jumper wires can be used by a user to create circuits representing situations a worker might encounter working on a real overhead power line to simulate the voltage difference a worker might experience during operation in that situation. The jumper wires can be used, for example to connect a conductor 104, 106, and 108 to another conductor 104, 106, 108, to connect a conductor 104, 106, 108 to the OPGW 110, or to connect a conductor 104, 106, 108 to a structure grounding point 112. This list is not intended to be exhaustive and jumper wires can be used to form connections not previously listed to create a variety of different voltage situations a worker may encounter. Similarly, during training, the jumper wires can be arranged by a user to establish an EPZ.

Jumpers can be configured to maintain a continuous current throughout a single conductor 104, 106, 108 or OPGW 110, without interruption despite any physical breaks in the conductor 104, 106, 108 or OPGW 110. In some embodiments, the jumpers may be used to connect conductors 104, 106, 108 and OPGWs 110 at power pole assemblies 102 extending from the right power pole 102 towards the middle power pole assembly 102. In alternative embodiments there may be no jumpers. In some embodiments, the jumpers may be used to connect conductors, 104, 106, 108 and OPGW 110 at power pole assemblies 102 other than the middle power pole assembly 102 (e.g., in embodiment with, for example five power pole assemblies, jumpers can be used to connect conductors 104, 106, 108 or OPGWs 110 at the power pole assembly 102 that is positioned second from the left or the power pole assembly 102 that is positioned second from the right. In some embodiments, the power line model 100 can be configured such that the center structure energizes at eight different potentials: the OPGW (left and right) and the three conductors (left and right).

In some embodiments, each conductor 104, 106, 108, and/or the OPGW 110 can include an inline resistor. The inline resistor can be configured to simulate a resistance corresponding to a long stretch of conductor, for example, 30 miles.

The first mounting board 120 can be configured to serve as a base for the power line model 100. The power pole assemblies 102 can be fixed to the first mounting board 120. In some embodiments the mounting board can comprise step leads 162. In some embodiments the mounting board can comprise step ridges 164 configured to demonstrate step and touch potential (see section on step potential model herein). In some embodiments, the mounting board can comprise step connection points 166. As mentioned previously, as the model is configured for training, the first mounting board 120 can, in some embodiments be configured for use on a tabletop. In some embodiments, electronic components, such as wires for energizing the conductors, are routed through, below, on, or behind the first mounting board 120.

The power line control system 122 can provide the three conductors 104, 106, 108 and/or other powered electrical components on the power line model 100 or first mounting board 120 with power in order to simulate high voltage situation involving overhead power lines. Despite simulating high voltage, the power line control system 122 can provide low voltage potential difference in order to simulate the danger situations a worker can encounter operating on high voltage power lines. In some embodiments, the power line control system 122 can be a low voltage three-phase power source.

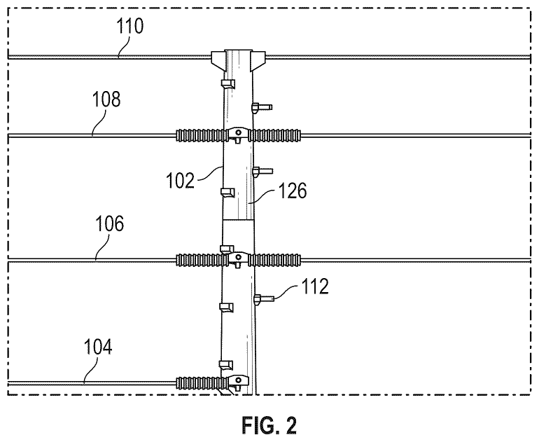

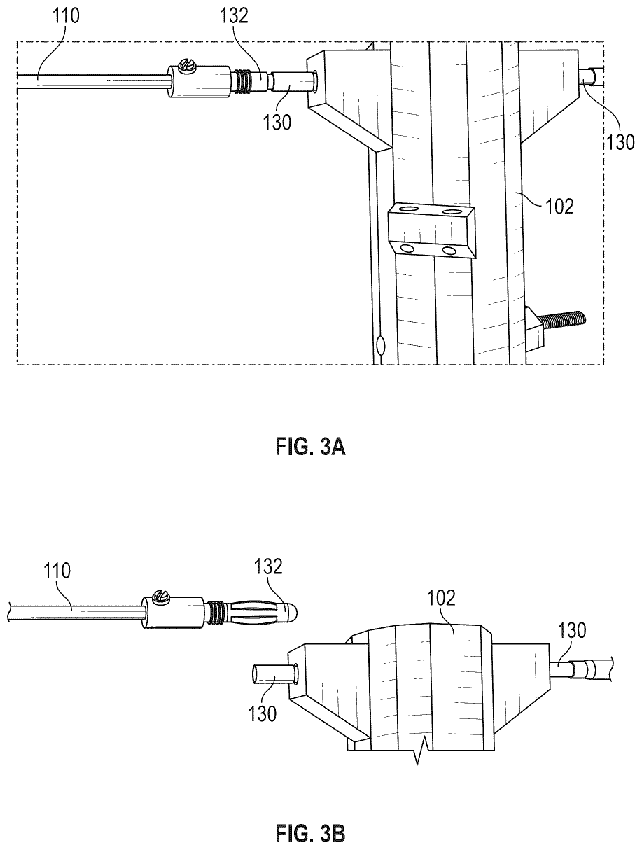

FIG. 2 shows an embodiment of a power pole assembly 102 of the power line model 100 shown in FIG. 1. The power pole assembly 102 comprises a bottom conductor 104, a middle conductor 106, and a top conductor 108, an OPGW 110, structure grounding points 112, insulators 124 and a power pole housing 126. In some embodiments (see FIG. 3), the power pole assembly 102 may have jumpers. As shown in FIG. 1, the power pole assemblies 102 can extend from the first mounting board 120. The power pole assemblies 102 can be configured to simulate overhead power poles to provide practical and hands-on training related to the same. The embodiment of the power line model 100 as shown in FIG. 1 includes three power pole assemblies 102. In other embodiments, the power line model 100 may include more power pole assemblies 102. For example, in other embodiments, the power line model 100 may include four, five, six or more power pole assemblies 102. Further, in other embodiments, the power line model 100 may have less power pole assemblies 102. For example, in other embodiments, the power line model 100 may include two or one power pole assemblies 102.

As shown in FIG. 2, the power pole assembly can include three conductors, a bottom 104, a middle 106 and a top 108 conductor. The conductors 104, 106, 108 can be configured to simulate conductors that can be found on overhead power poles. As mentioned above in reference to FIG. 1, a user can connect jumper wires to the conductors 104, 106, 108 to connect the conductors 104, 106, 108 to other conductors 104, 106, 108, the OPGW 110, the structure grounding points 112 and other components of the power line model 100 in order to demonstrate and teach safe and dangerous working arrangements. When the grounding simulator is turned on, the power line control system 122 can energize the conductors 104, 106, 108 by running a current through wires housed in the power pole housing 126 to the conductors 104, 106, 108. A lineman meter 230 (see FIGS. 8-12) can be coupled to the conductors 104, 106, 108 and other components of the power line model 100. The current that runs through the conductors can create a potential difference across the lineman meter 230 that the lineman meter 230 can display to show whether the lineman meter 230 is in a safe or dangerous working condition.

Although FIG. 2 shows a power pole assembly 102 having three conductors 104, 106, 108, other embodiments of the power pole assembly 102 can comprise of additional conductors 104, 106, 108 or fewer conductors 104, 106, 108. For example, in some embodiments, a power pole assembly 102 may have four, five, six or more conductors 104, 106, 108. In some embodiments, the power pole assembly 102 may have two or one conductors 104, 106, 108.

FIGS. 3A-3B show the top of a power pole assembly 102 with an OPGW 110. The top of the power pole assembly comprises connection port 130. The OPGW 110 comprises a connector 132 configured to couple to the connection port 130. In some embodiments, the power pole assembly 102 can have a connection port 130 on opposite sides of the power pole assembly 102 for each of the conductors 104, 106, 108, and the OPGW 110. For example, where there are three conductors and an OPGW 110, the power pole assembly 102 can have 8 connection ports. FIG. 3A depicts the connector 132 coupled to the connection port 130. FIG. 3B depicts the connector 132 separated from the connection port 130. In some embodiments the connector 132 can be a banana plug connector. In some embodiments the connection port 130 can be a banana plug connection port. In some embodiments the connector 132 can be configured to connect to the connection port 130 via a snap-fit configuration or a snap (press stud) configuration.

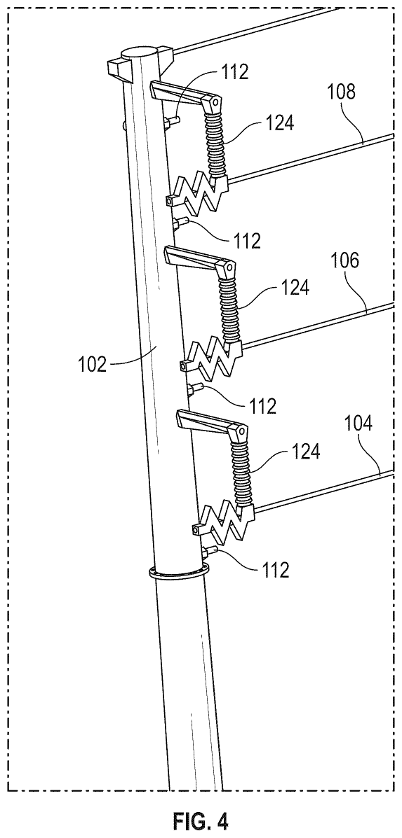

As shown in FIG. 4, the three conductors 104, 106, 108 are coupled to insulators 124. The insulators 124, or at least some of them, can be configured to suspend the conductors 104, 106, 108 and to provide a path for the current from the power line control system 122 to interact with the conductors 104, 106, 108 to energize them. In some embodiments of the power pole assembly 102 (see FIG. 2), the conductors 104, 106, 108 may be fixed to the power pole housing 126 to suspend the conductors 104, 106, 108.

Although FIG. 4 shows a power pole assembly 102 having three conductors 104, 106, 108, other embodiments of the power pole assembly 102 can comprise of additional conductors 104, 106, 108 or fewer conductors 104, 106, 108. For example, in some embodiments, a power pole assembly 102 may have four, five, six or more conductors 104, 106, 108. In some embodiments, the power pole assembly 102 may have two or one conductors 104, 106, 108.

As shown in FIG. 4, the three conductors 104, 106, 108 are coupled to insulators 124. The insulators 124, or at least some of them, can be configured to suspend the conductors 104, 106, 108 and to provide a path for the current from the power line control system 122 to interact with the conductors 104, 106, 108 to energize them. In some embodiments of the power pole assembly 102, the conductors 104, 106, 108 may be fixed to the power pole housing 126 to suspend the conductors 104, 106, 108.

Although FIG. 4 shows a power pole assembly 102 having three insulators 124, other embodiments of the power pole assembly 102 may have additional insulators 124 or fewer insulators 124. For example, in some embodiments, the power pole assembly 102 may have four, five, six or more insulators 124. In some embodiments, the power pole assembly 102 may have one or two insulators 124. Although FIG. 2 shows a power pole assembly 102 having the same number of insulators 124 as conductors 104, 106, 108, this need not be the case in all embodiments. For example, in some embodiments, the power pole assembly 102 may have three conductors 104, 106, 108 and two insulators 124.

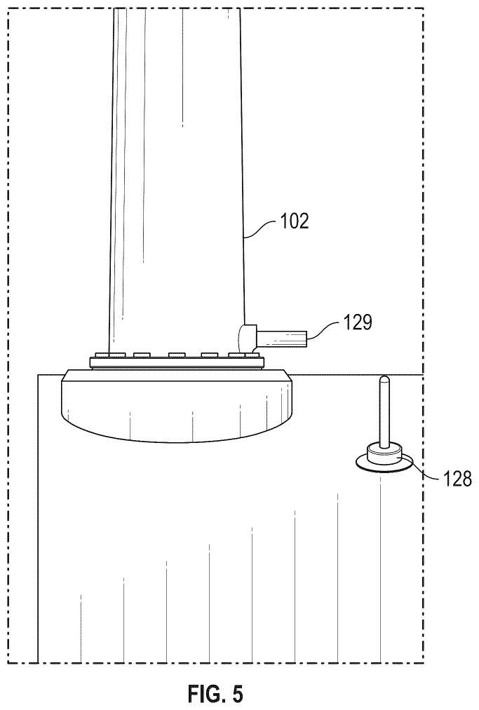

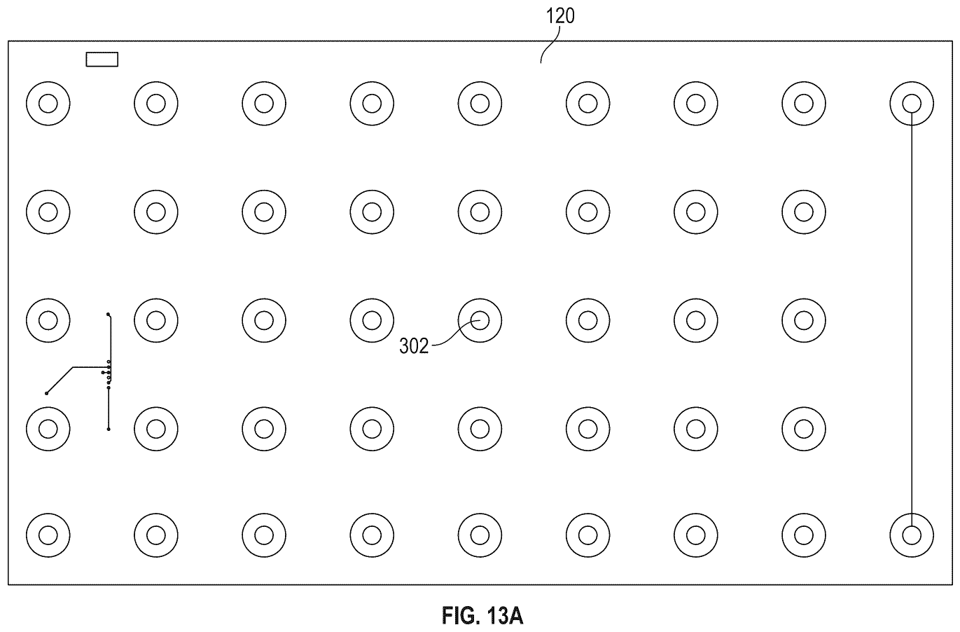

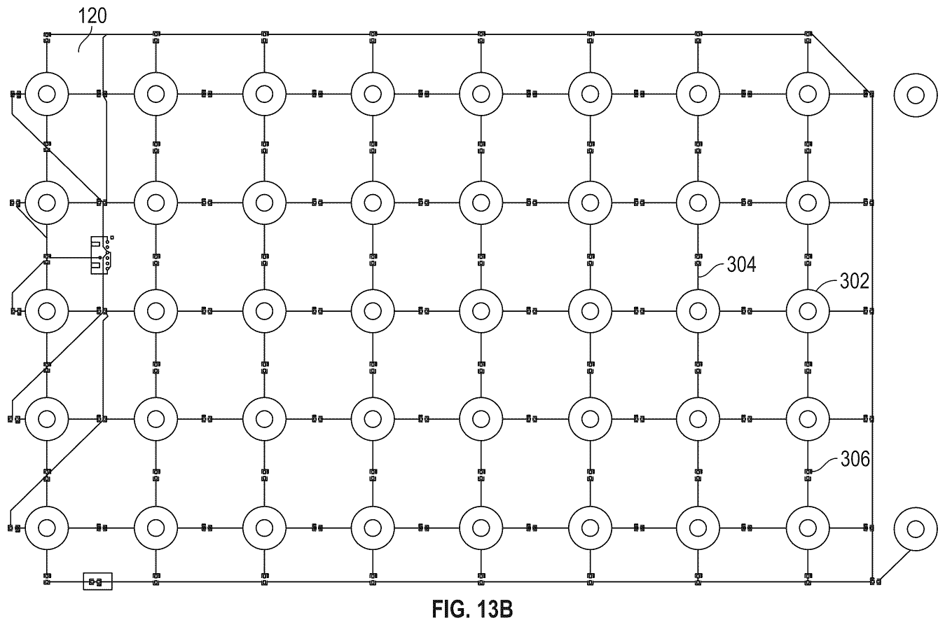

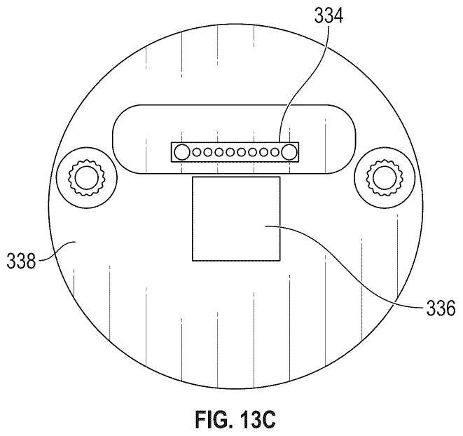

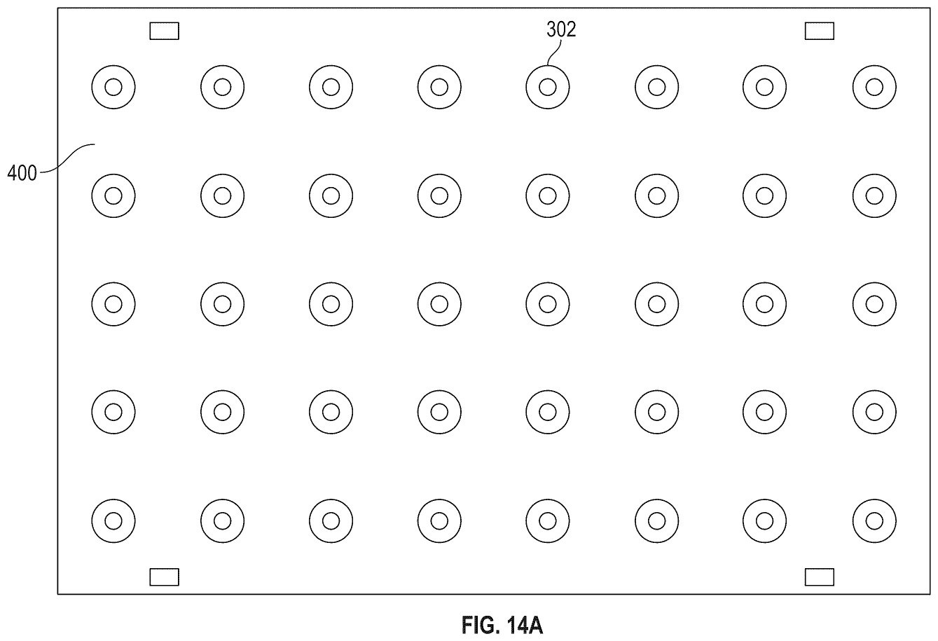

FIG. 5 shows the base of a power pole assembly 102. The base of the power pole assembly 102 is adjacent to a ground rod 128. The base has a connection point 129 that can be electrically coupled to the ground rod 128 via a lead. The setup shown in FIG. 5 can be configured to simulate the grounding of an overhead power line pole when the connection point 129 is electrically coupled to the ground rod. In some embodiments the ground rod 128 can have a magnetic base to enable attachment to the ground potential points 302 discussed in FIGS. 13A-13B and FIGS. 14A-14B. In some embodiments, the ground rods 128 can be configured to couple to the ground potential points 302 via a snap (press studs) or a snap fit.

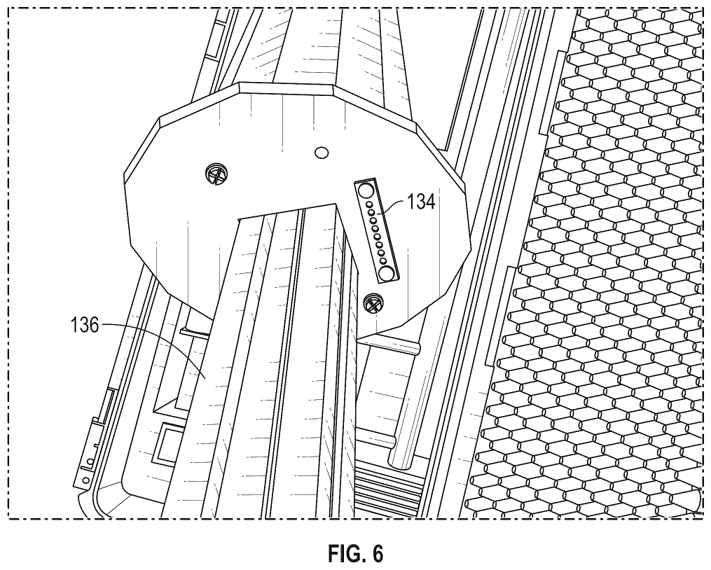

FIG. 6 shows the underside of the base of the power pole assembly 102 having a connection rod 136, and an electrical connection 134. In some embodiments, the first mounting board 120 can have an opening 236 configured to receive the connection rod 136 of the power pole assembly 102. In some embodiments the electrical connection 134 can be magnetic.

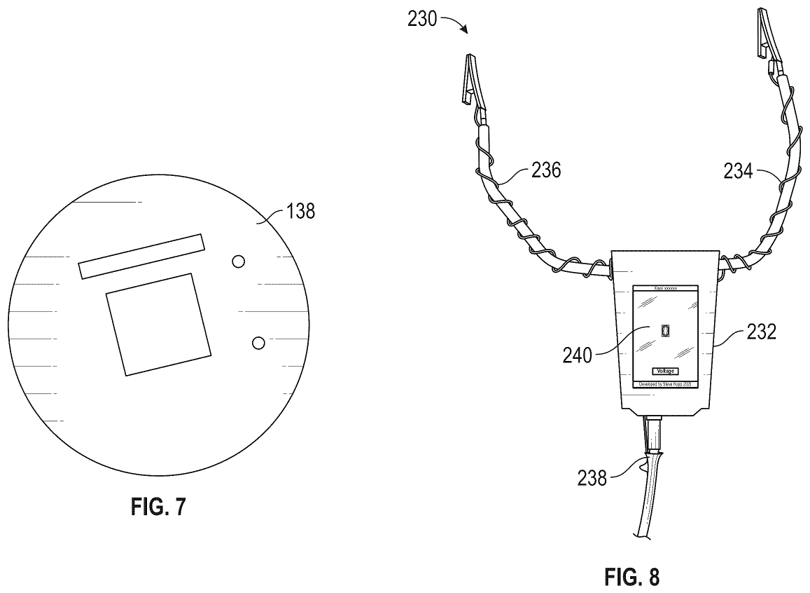

FIG. 7 shows a cover plate 138 for the underside of the base of the power pole assembly 102. The cover plate 138 having an opening for the connection rod 136 and an opening for the electrical connection 134.

### Lineman Meter

FIGS. 8-12 show embodiments of a lineman meter 230 configured for use with the grounding simulation model and exemplary applications of the lineman meter 230 with the power line model 100 of the grounding simulation model. The lineman meter 230 can be configured to approximate and simulate the body of a worker so that the grounding of a given grounding arrangement can be tested and displayed.

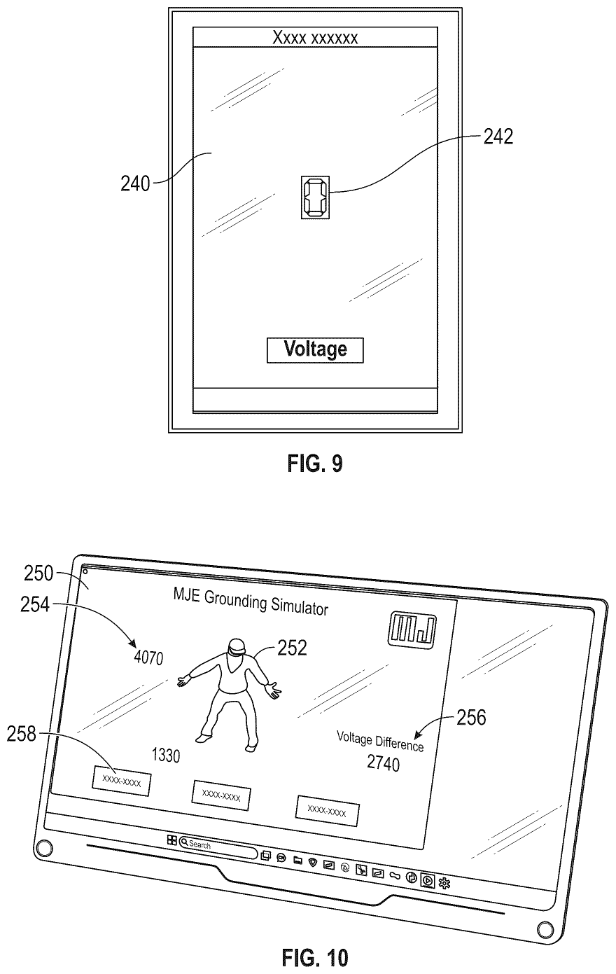

FIG. 8 shows an embodiment of a lineman meter 230. The lineman meter 230 comprises a housing 232, first and second appendage leads 234, 236, a connection 238 and a controls screen 240. The first and second appendage leads 234, 236 may be connected to various components of the grounding simulation model during training to simulate touchpoints between a lineman and the power equipment. The lineman meter 230 may have an internal resistance that approximates the resistance of the human body. For example, the lineman meter 230 may comprise a 1000 Ohm resistor. The lineman meter 230 may have internal resistance that approximates the resistance of the human body at a smaller scale. For example, in a low voltage situation, the resistor of the lineman meter 230 can be much less than 1000 Ohms to match the scale of the simulation voltage. In some embodiments, energizing the grounding simulation model may be accomplished using the controls screen 240 on the lineman meter 230. In some embodiments, the controls screen 240 comprise a tablet including a touchscreen, although other types of controls are possible. In some embodiments, the controls screen may comprise a voltage indicator 242 that can display the potential difference across the first and second appendage leads 234, 236 of the lineman meter 230 as depicted in FIG. 9. In some embodiments, the voltage indicator 242 can be adjusted to display other physical properties experienced by the lineman meter 230 such as current or resistance. The lineman meter 230 can include a connection 238 that connects the lineman meter 230 to an external screen with a grounding simulator application 250 downloaded and displayed on the external screen. This connection can provide power to the lineman meter 230 as well as allow for the transfer of information between the lineman meter 230 and the grounding simulator application 250. In some embodiments, the connection 238 can be omitted and the lineman meter 230 can be battery powered and/or wireless. In some embodiments, the connection 238 can be wireless, either through a network or via Bluetooth.

FIG. 10 shows an embodiment of a grounding simulator application 250 being run and displayed on an external screen. The grounding simulator application 250 can be configured to work with the lineman meter 230 in order to visually display the status of a lineman worker corresponding to the configuration of the lineman meter 230. This can help enhance education on grounding conditions by providing an easy to see and read visual of the status of a lineman. The grounding simulator application 250 as shown in FIG. 10 comprises a virtual lineman 252, appendage point voltage indicators 254, voltage difference indicator 256 and appendage configuration buttons 258. In some embodiments, the external screen can be a tablet screen or computer screen. In other embodiments, the external screen can be a screen of a different device capable of downloading and displaying a computer application.

The virtual lineman 252 can be a graphical representation of a lineman worker. The appendages of the virtual lineman 252 can mirror the position of the first and second appendage leads 234, 236 so the lineman meter 230 can be visually displayed to learners in a recognizable manner. The appendage point voltage indicators 254 can be configured to display the voltage measured by the lineman meter 230 at the first and second appendage leads 234, 236. The appendage point voltage indicators 254 can display the measured voltage on the grounding simulator application 250 around the appendage on the virtual lineman 252 corresponding to the assigned appendage of the appendage leads 234, 236. The voltage difference indicator 256 can display the difference in voltage between the measured voltages at the two appendage leads 234, 236. This can provide an easy to understand visual to learners about whether the lineman meter 230 is configured in a safe working environment (e.g., proper grounding) or a hazardous working environment (e.g., improper grounding).

Appendages can be assigned to the appendage leads 234, 236 with the appendage configuration buttons 258. For example, in FIG. 10 there are three appendage configuration buttons 258, “Hand-Hand,” “Hand-Foot” and “Foot-Foot.” If a user clicks the “Hand-Foot” appendage configuration button 258, the voltage measured at the first appendage lead 234 will be displayed by an appendage point voltage indicator 254 near a hand of the virtual lineman 252 and the voltage measured at the second appendage lead 236 will be displayed by an appendage point voltage indicator 254 near a foot of the virtual lineman 252. The three appendage configuration buttons 258 shown in FIG. 10 are not meant to be exhaustive of all the appendage configuration buttons 258 that can be displayed on the grounding simulator application 250 and are merely illustrative of some examples of appendage configuration buttons 258.

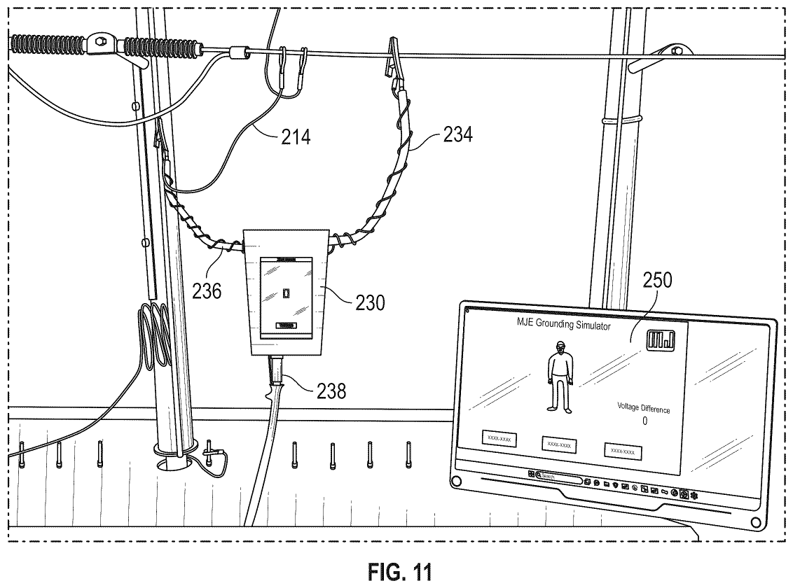

FIG. 11 shows the lineman meter 230 coupled to a power line model 100 in a safe setting (e.g., proper grounding). The first appendage lead 234 is coupled to the bottom conductor 104 and the second appendage lead 236 is coupled to a grounding wire of a power pole assembly 102. A jumper wire 214 is coupled to the grounding wire positioned below the second appendage lead 236 and to the bottom conductor 104. Since the appendage leads 234, 236 are coupled to the power line model 100 in a safe configuration, the voltage indicator 242 on the lineman meter 230 displays zero and the voltage difference indicator 256 on the grounding simulator application 250 displays zero.

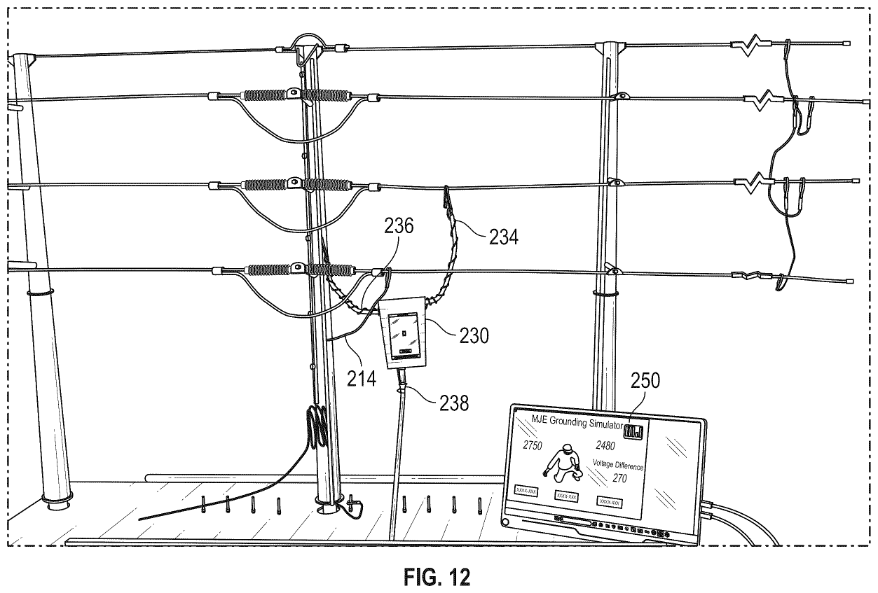

In contrast, FIG. 12 shows the lineman meter 230 coupled to a power line model 100 in a hazardous setting (e.g., improper grounding). The first appendage lead 234 is coupled to the middle conductor 106 and the second appendage lead 236 is coupled to a grounding wire of a power pole assembly 102. A jumper wire 214 is coupled to the grounding wire positioned below the second appendage lead 236 and to the bottom conductor 104. However, no jumper wire 214 is connecting the middle conductor 106, where the first appendage lead 234 is coupled to, to the bottom conductor 104, creating a hazardous condition. Since the appendage leads 234, 236 are coupled to the power line model 100 in a hazardous configuration, the voltage indicator 142 on the lineman meter 230 displays 270 volts and the two appendage point voltage indicators 254 display 2750 volts and 2480 volts. The voltage difference indicator 256 displays 270 volts which matches the voltage indicator 242.

### Step and Touch Potential Model

When working on overhead power lines, it is important to provide the utility pole a path to ground. In practice, the utility pole is jumpered to a ground rod that is anchored in the ground in order to provide the path to ground. However, this energizes the area immediately surrounding the ground rod in a ripple pattern emanating from the ground rod in the form of potential rings. A similar occurrence can occur when a powered wire falls and contacts the ground or an object on the ground (e.g., a truck) comes in contact with a powered wire. The voltage of the potential rings decrease the further the ring is from the energized object. However, a worker in the area can accidentally create a potential difference across his or her body if one of the worker's feet within one potential ring and the worker's other foot is within a different potential ring. This can create a current through the worker from one foot to the other that can be dangerous.

FIG. 13A shows a top view of a portion of a surface of first mounting board 120. The first mounting board 120 can comprise at least one ground potential point 302. The ground potential points 302 can be arranged in a grid pattern (or a matrix) as depicted in FIG. 13A. The ground potential points 302 can have equidistant spacing or can be spaced with varying distances. The ground potential points 302 can be magnetic, for case of connection with other components of the step and touch potential model. In some embodiments, the ground potential points 302 can be configured with some other coupling mechanism to enable coupling of additional components of the power line model 100 to be coupled to the grounding board. In some embodiments, the ground potential points 302 can be configured to couple to other components via snap-fits. In some embodiments the ground potential points 302 can be configured to be coupled to additional components via quarter-turn fasteners. In some embodiments, the ground potential points 302 can be configured couple to other components via snaps (or press studs). In some embodiments, the ground potential points 302 can be configured to conduct electricity. While the ground potential points 302 appear to be disk shaped in FIG. 13A, they are not limited to a disk shape. In some embodiments the ground potential points can be square, or triangular or any other shape.

FIG. 13B shows an internal view of a portion of the first mounting board 120. As illustrated in FIG. 13A the first mounting board 120 can comprise at least one ground potential point 302. The ground potential points 302 can be electrically coupled by wires 304 that run between the ground potential points 302. At least one resistor 306 can be coupled to the wires 304 that run between the ground potential points 302. In some embodiments there can be a resistor between every ground potential point 302 such that an electrical current must pass through a resistor 306 when traveling from one ground potential point 302 to an adjacent ground potential point 302. In some embodiments the resistors 306 can have 150 ohms of resistance.

FIG. 13C shows a power pole assembly 102 connection point 338 on a first mounting board 120. In some embodiments the connection point 338 can be configured to have an electrical connection point 334. In some embodiments the electrical connection point have 8 pins to output a variety of voltages received from a power source. In some embodiments the electrical connection point can have 5 pins. In some embodiments the electrical connection point 334 can have any number of pins from 1 to 8. In some embodiments, the electrical connection point 334 can have a number of pins equal to twice that of the total number of OPGWs 110, and conductors 104, 106, and 108 present within the power line model 100 such that each side of the OPGWs 110 and conductors 104, 106, and 108 can receive a different voltage from a power source. For example, if there is one OPGW and three total conductors 104, 106, and 108, the electrical connection point 334 may have 8 pins. In another example if there is one OPGW 110 and four total conducts 104, 106, and 108 the electrical connection point 334 may have 10 pins. In some embodiments the electrical connection point 334 can be magnetic. In some embodiments the connection point 338 can have an opening 336. In some embodiments the opening 336 can be configured to house the connection rod 136 of the power pole assembly 102. In some embodiments, the opening 336 can be large enough to house the entirety of a connection rod 136 of the power pole assembly. This can be advantageous because the opening 336 in combination with the connection rod 136 can provide a means of holding the power pole assembly 102 in place the grounding simulation model is in use.

FIG. 14A shows a top view of a surface of a second mounting board 400. The second mounting board 400 can comprise at least one ground potential point 302. As depicted in FIG. 13A, the ground potential points 302 can have equidistant spacing or can be spaced with varying distances. The spacing of the ground potential points 302 on the second mounting board 400 may vary from the spacing of the ground potential points on the first mounting board 120. The ground potential points can be magnetic to facilitate connection with other components of the step and touch potential model. The ground potential points 302 can be configured to conduct electricity.

FIG. 14B shows an internal view of the second mounting board 400. As illustrated in FIG. 14A the second mounting board 400 can comprise at least one ground potential point 302. The ground potential points 302 can be electrically coupled by a wire 304 that runs between the ground potential points 302. At least one resistor 306 can be coupled to the wire 304 that runs between the ground potential points 302. In some embodiments there can be a resistor 306 between every ground potential point 302 such that an electrical current must pass through the resistor 306 when traveling from one ground potential point 302 to an adjacent ground potential point 302. In some embodiments the resistor can have 150 ohms of resistance.

In some embodiments, the first mounting board 120 and the second mounting board 400 can be combined into one mounting board. This can be advantageous because it can conserve space required for the electrical grounding simulator. It can also be advantageous as it can decrease the number of components that are required to assemble and use the electric grounding simulator. Further, combining the two boards into one can be advantageous as it reduces the total weight of the electric grounding simulator and thus makes it easier to transport.

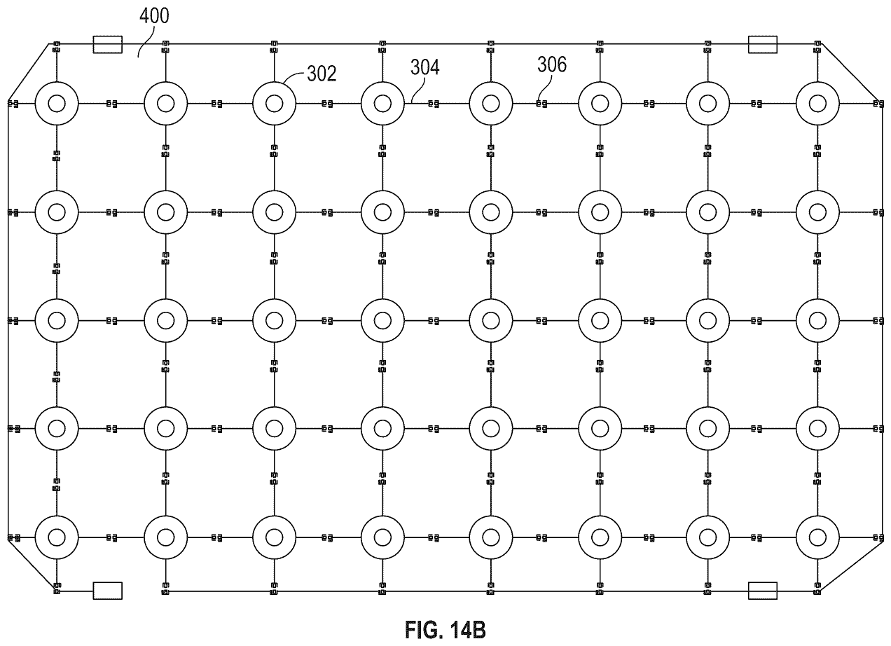

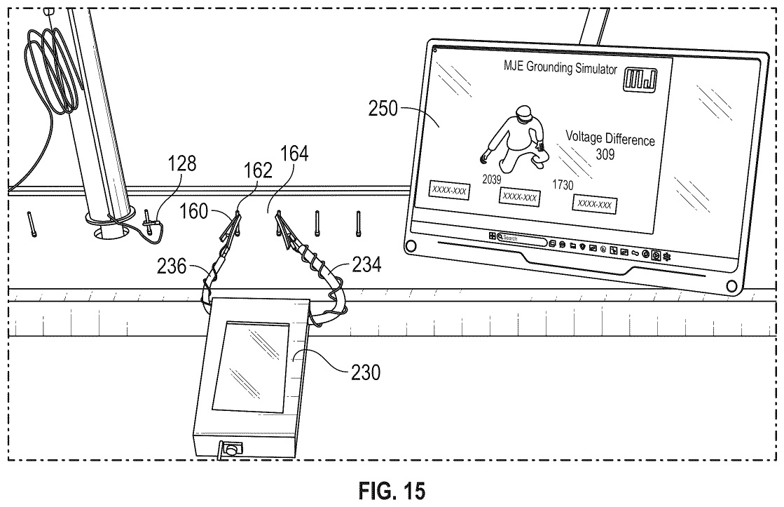

FIG. 15 shows a lineman meter 230 coupled to a grounding simulation model comprising a step and touch potential model 160. The step and touch potential model 160 can comprise a ground rod 128, step leads 162 and step ridges 164. In some embodiments, as shown in FIG. 15, the step and touch potential model 160 can be arranged on a first mounting board 120 that also has a power line model 100 arranged on the first mounting board 120. However, in other embodiments, the step and touch potential model 160 may be arranged on a first mounting board 120 that does not have a power line model 100 arranged on the mounting board.

As shown in FIG. 15, the step ridges 164 can have different sizes. This can represent and be used to educate that the potential rings that form from an energized object contacting the ground get weaker the further the potential ring is from the energized object. In the embodiment shown in FIG. 15, the smaller step ridges 164 can indicate a weaker potential ring while larger step ridges 164 can indicate a stronger potential ring. In other embodiments, larger step ridges 164 can indicate a weaker potential ring while smaller step ridges 164 can indicate a stronger potential ring.

The step leads 162 can be positioned in the step ridges 164. Inside the first mounting board 120, a wire from the power line control system 122 runs across the ground rod 128 and step leads 162 that can provide power to the ground rod 128 and step leads 162. Resistors 306 can be positioned along the wire in between adjacent step leads 162 to simulate voltage drops the further away a step lead 162 is from the ground rod 128. The ground rod 128 and step leads 162 can be configured to allow the appendages 234, 236 of the lineman meter 230 to couple to them to measure potential difference. In some embodiments the step leads 162 may be positioned on a first mounting board 120 with magnetic ground potential points 302.

It should be appreciated that although the embodiment of a step and touch potential model 160 comprises four step leads 162 and four step ridges 164, other embodiments may include more or fewer step leads 162 and step ridges 164. For example, in some embodiments, there may be five, six or seven or more step leads 162 and step ridges 164 or three, two or one step leads 162 and step ridges 164. It should also be appreciated that the number of step leads 162 does not need to equal the number of step ridges 164.

FIG. 15 shows the lineman meter 230 coupled to the step and touch potential model 160 to measure a potential difference between to step leads 162. The first appendage lead 234 is coupled to the second step lead 162 from the ground rod 128. The second appendage lead 236 is coupled to the first step lead 162 from the ground rod 128. As shown in FIG. 11, the voltage indicator 242 on the lineman meter 230 displays 400 volts and the two appendage point voltage indicators 254 display 2130 volts and 1730 volts. The voltage difference indicator 256 displays 400 volts which matches the voltage indicator 242.

### Wire Puller Potential Model

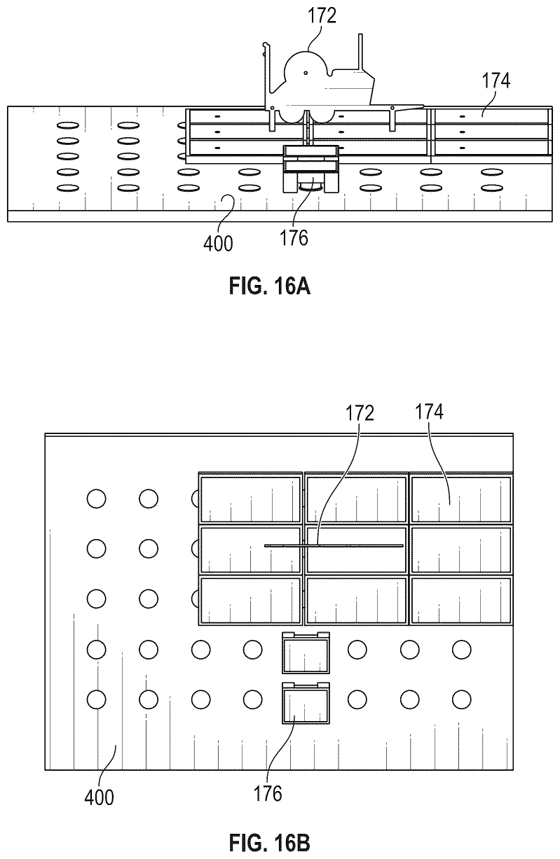

FIGS. 16A-23B show embodiments of a grounding simulation model comprising a wire puller potential model 170 that is configured to educate on establishing proper grounding when using wire-pulling and stringing equipment that can become energized in use during operation on overhead power lines. The wire puller potential model 170 can comprise a model wire puller 172, grounding mats 174, insulation and isolation mats 176, and a second mounting board 400. FIG. 16A shows a front view of a wire puller potential model 170 that is configured to educate on establishing proper grounding when using wire-pulling and stringing equipment that can become energized during operation on overhead power lines.

FIG. 16B shows a top-down view of a wire puller potential model 170. The wire puller model 170 can comprise the same components depicted in FIG. 16A.

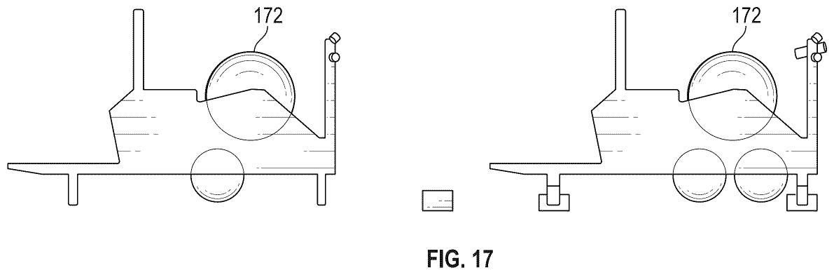

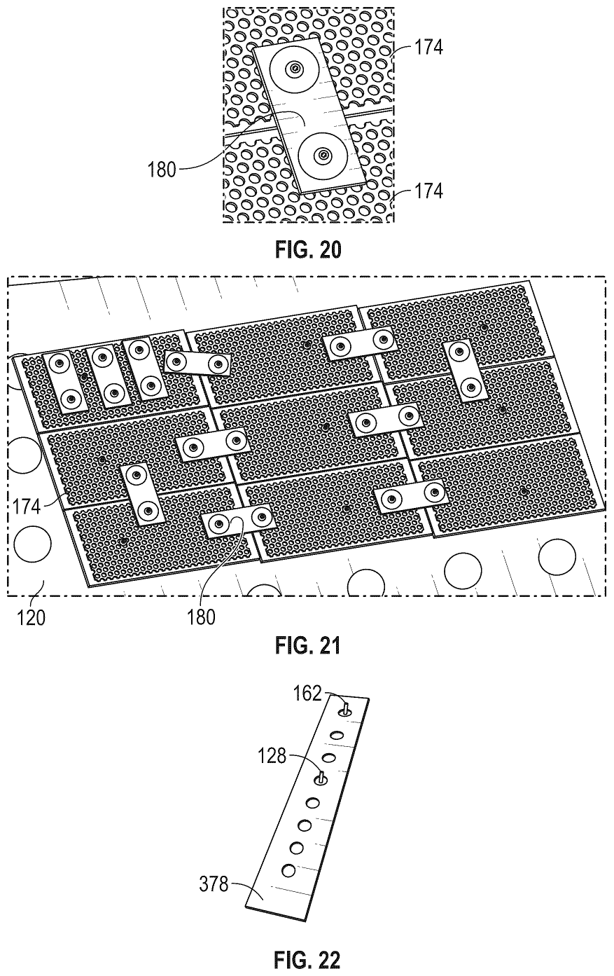

FIGS. 16A-16B show an embodiment of a model wire puller 172 positioned on grounding mats 174 and insulation or isolation mats 716. This model simulates the manner in which grounding mats 174 are used in the field to create an EPZ. For example, grounding mats 174 are arranged to create a ground grid. A ground grid is a system of interconnected bare conductors, metallic surface mats, and/or grating, arranged in a pattern over a specified area. Normally, it is bonded to ground rods driven around and within its perimeter to increase its grounding capabilities and provide convenient connection points for grounding devices. The primary purpose of the grid is to provide safety for workers by limiting potential differences within its perimeter to safe levels in case of high currents which could flow if the circuit being worked on became energized for any reason or if an adjacent energized circuit faulted. When used, these grids are employed at pull, tension and splice sites. As shown in FIGS. 20-21, the model can include models of ground mats 174 and connection points or straps 180, which are used to simulate connection of grounding mats to each other. This allows for modeling of the grounding mats 174 setup as well as the equipment connected to them. Improper set up can cause hazardous differences of potential and so simulating this in the training model can be important. FIG. 17 shows embodiment of two model wire puller 172 renderings.

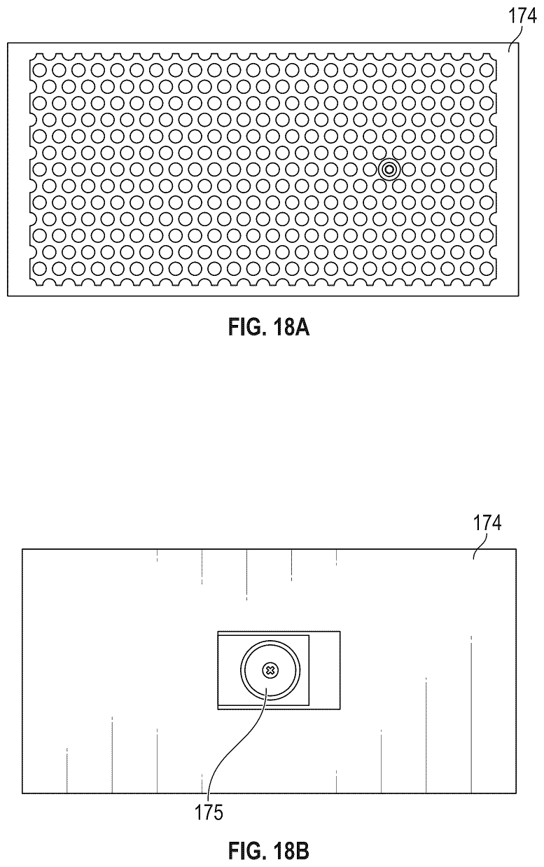

FIG. 18A depicts a top-down view of grounding mat 174. In some embodiments the grounding mat 174 can have a metallic grating coupled to the top portion, as shown in FIG. 18A. In some embodiments the grounding mats 174 may have a different metal covering affixed to the top portion. In some embodiments the different metal covering can be a sheet of metal to cover the surface of the grounding mats 174. In some embodiments the metal covering can be coupled to the grounding mats 174 via a screw or a nail. In some embodiments, the grounding mats 174 can be made of metallic material such that the top portion does not require an additional component to attach a metal covering. In some embodiments, the metallic covering can be magnetic.

FIG. 18B depicts the bottom of a grounding mat 174. The grounding mat 174 having a connection point 175, where the connection point is configured to enable the grounding mat 174 to be electrically coupled to the ground potential points 302 of the first mounting board 120 or ground potential points 302 of the second mounting board 400. In some embodiments the connection point 175 is configured to be magnetic in order to connect to the ground potential points 302. In some embodiments, the connection point 175 can be configured to couple to the ground potential points 302 via snap-fits. In some embodiments the connection point 175 can be configured to be coupled to the ground potential points 302 via quarter-turn fasteners. In some embodiments, the connection point 175 can be configured couple to the ground potential points 302 via snaps (or press studs).

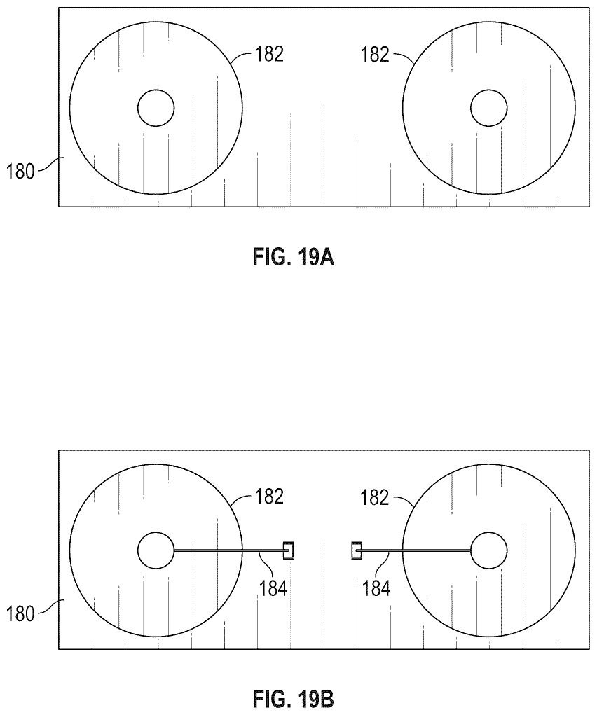

FIGS. 19A-19B show a connection strap 180. In FIG. 19A the connection strap 180 comprise connection points. In some embodiments the connection points 182 can be positioned on opposite sides of the connection strap 180. FIG. 19B depicts an internal schematic of the connection strap 180. As shown in FIG. 19B. The connection strap 180 can have a lead 184 running between the at least two connection points 182 so that the two connection points are electrically coupled via the lead 184. This means that if the connection point 182 on one end of the connection strap 180 is experiencing an electrical charge, the connection point 182 on the other end of the connection strap 180. In some embodiments the connection strap 180 can be configured to connect two grounding mats 174. As shown in FIG. 20 the connection strap 180 is placed across two grounding mats 174 such that one of the connection points 182 is in contact with one of the grounding mats 174 and the other connection point 182 is in contact with a second grounding mat. In some embodiments, the connection strap 180 can be used to electrically couple grounding mats 174. As shown in FIG. 20 the connection strap 180 is laid across two grounding mats 174 such that one connection point 182 is on each grounding mat 174. In this example the connection points 182 are electrically coupled via the lead 184 and so if one of the grounding mat 174 experiences an electrical charge, that charge will flow through the connection strap 180 to the second grounding mat 174. In some embodiments, multiple connection straps 180 can be used to connect multiple grounding mats 174 so that all grounding mats 174 are electrically coupled via the connection strap 180. This is depicted in FIG. 21 where the connection straps 180 connect the grounding mats 174 in an “S” pattern. Despite the fact that each grounding mat 174 is not directly connect to each other grounding mat 174 via a connection strap 180, they are all electrically coupled because the “S” shaped connection pattern creates a cohesive path for electricity to flow from one grounding mat 174 to all other grounding mats 174.

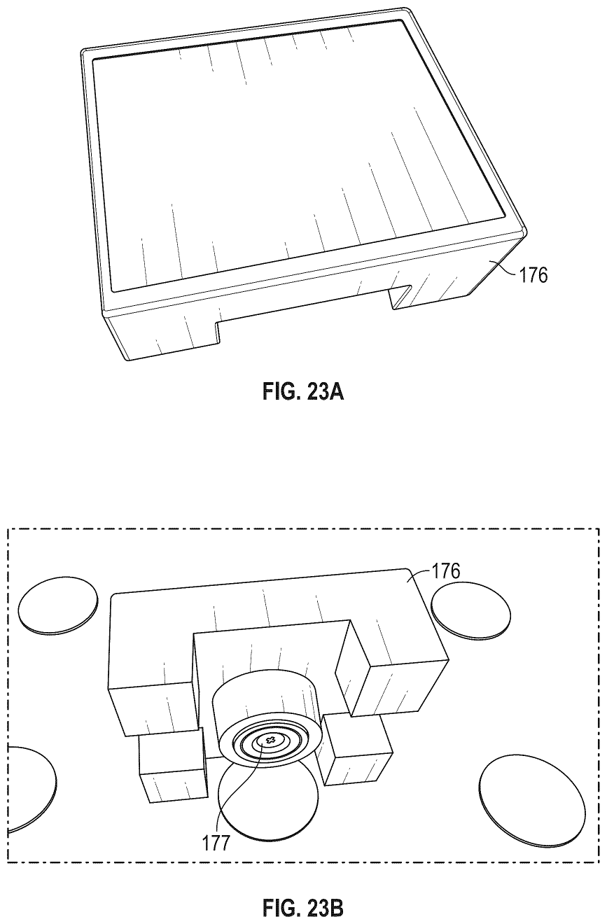

FIG. 22 shows an embodiment of a grounding board 378 that can be used in a wire potential model 170. As shown in FIG. 22, the grounding board 378 comprises a ground rod 128 and a step lead 162. The model wire puller 172 can be coupled with a jumper wire 214 to the ground rod 128 in order to ground the model wire puller 172 when energized. The step lead 162 can be used in conjunction with the ground rod 128 to show that the grounding of the model wire puller 172 creates step and touch potential as discussed herein in the step and touch potential model section.

FIGS. 23A-23B show an embodiment of an insulation mats 176. In some embodiments the insulation or isolation mats 176 are made out of a material that does not conduct electricity. For example, the insulation or isolation mat 176 can be made out of materials including but not limited to rubber, glass, plastics, ceramics, and dry wood. In some embodiments the insulation or isolation mat can have four legs protruding from the bottom, as depicted in FIG. 23B. In some embodiments, the insulation or isolation mats can comprise a connection point 177 on the bottom of the insulation or isolation mat. In some embodiments the connection point 177 can be magnetic so that it can be coupled with a magnetic ground potential points 302 of a first mounting board 120 or second mounting board 400. In some embodiments the connection point 177 can be configured to couple to the ground potential points 302 by a means including but not limited to, snaps (press studs), a quarter-turn fastener, or snap-fits.

### Substation Potential Model

In some embodiments, the grounding simulation model of the present disclosure may comprise a substation potential model. The substation potential model can be configured to demonstrate the potential difference across substation equipment and other equipment that are used at these sites.

### Mobile Equipment Potential Model

In some embodiments, the grounding simulation model of the present disclosure may comprise a mobile equipment potential model. The mobile equipment potential model can be configured to show that step and touch potential and EPZ bonding of insulated and uninsulated equipment.

### URD Grounding and Switching Model

In some embodiments, the grounding model of the present disclosure may comprise a URD (underground residential distribution) grounding and switching model. The URD grounding and switching model can be configured to demonstrate switching, EPZ bonding, and grounding of URD equipment (e.g., padmounts, riser poles, etc.) and cables

### Disassembled Model and Carry Case

In some embodiments, the grounding simulation model of the present disclosure may be disassembled into smaller components and packaged within a carrying case. The carrying case can be configured with compartments specifically shaped for each of the various components of the grounding simulation model of the present disclosure.

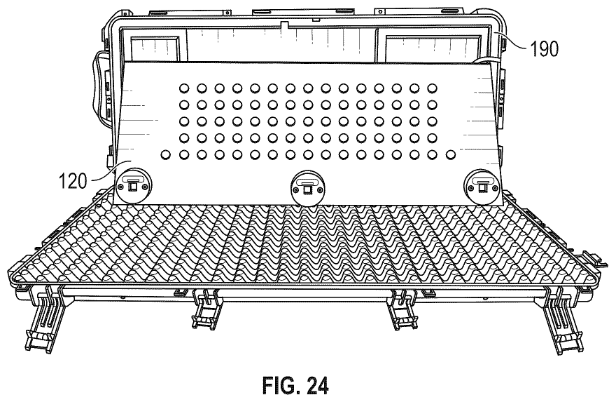

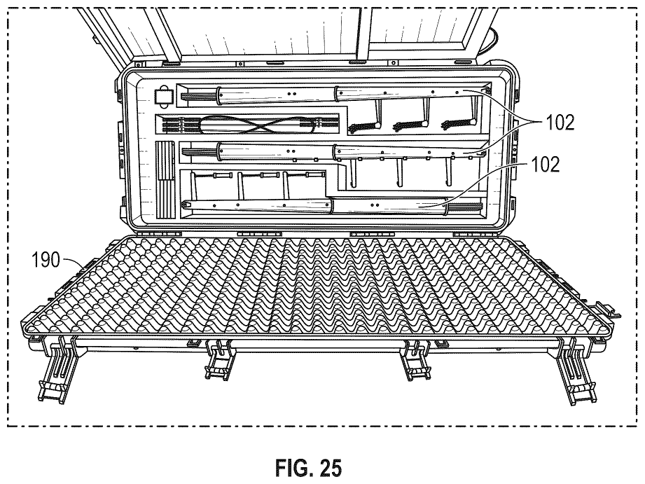

FIG. 24 shows a top-down view of a carrying case 190, configured to hold at least one first mounting board 120 placed inside the case. In some embodiments, the carrying case 190 can be a protective case. In some embodiments, the carrying case 190 can be a case with additional foam padding. In some embodiments, the carrying case 190 can be a waterproof case. In some embodiments, the carrying case 190 can have compartments that are shaped to hold specific components of the grounding simulation model. For example, the carrying case 190 can have a compartment with the same shape as a first mounting board 120 or a power pole assembly 102 to indicate the appropriate placement for a specific component and protect the components while they are transported from one location to another. In another example, as depicted in FIG. 26, the compartments can be sized to specifically house the power pole assemblies 102 and other components of varying sizes. This can be advantageous to minimize the movement of the components during travel and prevent damage from components hitting each other or the edges of the case.

From the foregoing description, it will be appreciated that inventive training labs are disclosed. While several components, techniques and aspects have been described with a certain degree of particularity, it is manifest that many changes can be made in the specific designs, constructions and methodology herein above described without departing from the spirit and scope of this disclosure.

Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as any subcombination or variation of any subcombination.

Moreover, while methods may be depicted in the drawings or described in the specification in a particular order, such methods need not be performed in the particular order shown or in sequential order, and that all methods need not be performed, to achieve desirable results. Other methods that are not depicted or described can be incorporated in the example methods and processes. For example, one or more additional methods can be performed before, after, simultaneously, or between any of the described methods. Further, the methods may be rearranged or reordered in other implementations. Also, the separation of various system components in the implementations described above should not be understood as requiring such separation in all implementations, and it should be understood that the described components and systems can generally be integrated together in a single product or packaged into multiple products. Additionally, other implementations are within the scope of this disclosure.

Conditional language, such as “can,” “could,” “might,” or “may,” unless specifically stated otherwise, or otherwise understood within the context as used, is generally intended to convey that certain embodiments include or do not include, certain features, elements, and/or steps. Thus, such conditional language is not generally intended to imply that features, elements, and/or steps are in any way required for one or more embodiments.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately,” “about,” “generally,” and “substantially” may refer to an amount that is within less than or equal to 10% of, within less than or equal to 5% of, within less than or equal to 1% of, within less than or equal to 0.1% of, and within less than or equal to 0.01% of the value amount.

Some embodiments have been described in connection with the accompanying drawings. The figures are drawn to scale, but such scale should not be limiting, since dimensions and proportions other than what are shown are contemplated and are within the scope of the disclosed inventions. Distances, angles, etc. are merely illustrative and do not necessarily bear an exact relationship to actual dimensions and layout of the devices illustrated. Components can be added, removed, and/or rearranged. Further, the disclosure herein of any particular feature, aspect, method, property, characteristic, quality, attribute, element, or the like in connection with various embodiments can be used in all other embodiments set forth herein. Additionally, it will be recognized that any methods described herein may be practiced using any device suitable for performing the recited steps.

While a number of embodiments and variations thereof have been described in detail, other modifications and methods of using the same will be apparent to those of skill in the art. Accordingly, it should be understood that various applications, modifications, materials, and substitutions can be made of equivalents without departing from the unique and inventive disclosure herein or the scope of the claims.

What is claimed is:

1. A simulation model for providing EPZ grounding training, the simulation model comprising:
a power line model comprising:
a control system;
at least one power pole assembly configured to support at least one conductor;
at least one conductor coupled to the at least one power pole assembly, configured to receive and carry a current supplied from the control system;
a mounting board configured to mount the at least one power pole assembly;
the mounting board comprising at least one ground potential point, wherein the at least one ground potential points are:
magnetic; and
electrically coupled by a wire that runs between the at least one ground potential points;
a lineman meter configured for use during EPZ grounding training, the lineman meter comprising:
at least two appendage leads;
a lineman meter housing; and
a control screen configured to display a measured potential difference between the at least two appendage leads.

2. The simulation model of claim 1, wherein a resistor is positioned on the wire between adjacent at least one ground potential points.

3. The simulation model of claim 1, wherein the power line model further comprises at least one OPGW.

4. The simulation model of claim 3, wherein the at least one power pole assembly comprises at least one structure grounding point.

5. The simulation model of claim 4, wherein the mounting board comprises at least one grounding rod configured to provide a path to ground for the at least one power pole assembly.

6. The simulation model of claim 5, wherein the power line model further comprises at least one jumper wire configured to arrange grounding setups for providing EPZ grounding training.

7. The simulation model of claim 6, wherein the lineman meter is configured to be attached to the at least one conductor of the power line model using the at least two appendage leads to provide EPZ grounding training.

8. The simulation model of claim 7 further comprising a grounding simulator application, wherein the lineman meter is configured to interact with the grounding simulator application to display the measured potential difference on an external screen.

9. The simulation model of claim 8, wherein the lineman meter is configured to interact with the grounding simulator application to further display a measured potential at each of the at least two appendage leads.

10. A simulation model for providing EPZ grounding training, the simulation model comprising:
a power line model comprising:
a control system;
at least one power pole assembly configured to support at least one conductor;
at least one conductor coupled to the at least one power pole assembly, configured to receive and carry a current supplied from the control system;
a mounting board configured to mount the at least one power pole assembly;
the mounting board comprising at least one ground potential point, wherein the at least one ground potential point is:
magnetic; and
a lineman meter configured for use during EPZ grounding training, the lineman meter comprising:
at least two appendage leads;
a lineman meter housing; and
a control screen configured to display a measured potential difference between the at least two appendage leads.

11. The simulation model of claim 1 further comprising a step and touch potential model comprising at least one step lead magnetically coupled to one of the at least one ground potential points.

12. The simulation model of claim 11, wherein the step and touch potential model is positioned on the mounting board.

13. The simulation model of claim 12, wherein a wire positioned in the mounting board runs between the at least one ground potential points to electrically couple the at least one ground potential points.

14. The simulation model of claim 13, wherein a resistor is positioned on the wire between adjacent at least one ground potential points.

15. The simulation model of claim 14, wherein the lineman meter is configured to be attached to the at least one step lead using the at least two appendage leads to provide EPZ grounding training.

16. The simulation model of claim 15 further comprising a grounding simulator application, wherein the lineman meter is configured to interact with the grounding simulator application to display the measured potential difference on an external screen.

17. A simulation model for providing EPZ grounding training, the simulation model comprising:
a power line model comprising:
a control system;
at least one power pole assembly configured to support at least one conductor;
at least one conductor coupled to the at least one power pole assembly, configured to receive and carry a current supplied from the control system;
a mounting board configured to mount the at least one power pole assembly;
the mounting board comprising at least one ground potential point, wherein the at least one ground potential point is magnetic;
a lineman meter configured for use during EPZ grounding training, the lineman meter comprising:
at least two appendage leads;
a lineman meter housing; and
a control screen configured to display a measured potential difference between the at least two appendage leads.

18. The simulation model of claim 17, wherein the at least one ground potential points are arranged in a grid pattern.

19. The simulation model of claim 17, wherein the at least one ground potential points are electrically coupled by a wire that runs between the at least one ground potential points.

20. The simulation model of claim 19, wherein a resistor is positioned on the wire between adjacent at least one ground potential points.
